(19) United States
(12) Patent Application Publication
(10) Pub. No.: US 2006/0051975 A1
(43) Pub. Date: Mar. 9, 2006

(54) Novel deposition of SiON dielectric films

(76) Inventors: Ashutosh Misra, Plano, TX (US); Matthew Fisher, Allen, TX (US); Benjamin Jurcik, Richardson, TX (US)

Correspondence Address: AIR LIQUIDE, 2700 POST OAK BOULEVARD, SUITE 1800, HOUSTON, TX, 77056, US

(21) Appl. No.: 10/935,759

(22) Filed: Sep. 7, 2004

(51) Int. Cl. H01L 21/31

(52) U.S. Cl. 438/778

(57) ABSTRACT

This disclosure discusses the forming of gate dielectrics in semi conductor devices, and more specifically to forming thin high-k dielectric films on silicon substrates typically using chemical vapor deposition or atomic layer deposition processes. The current invention forms a dielectric film in a single film-forming step using a vapor phase silicon precursor in conjunction with a nitrogen source and an oxygen source for the deposition of a silicon oxy nitride (SiON) film of desired stochiometry. The vapor phase silicon precursor, nitrogen source and oxygen source are carbon and chlorine free, eliminating the undesirable effects of carbon and chlorine in the dielectric film or solid deposits in the chamber exhaust.

### BACKGROUND

Manufacturing of semiconductor devices employs a thin gate dielectric, typically silicon dioxide, between the underlying silicon substrate and the gate electrode. Depositing a thin dielectric film on a silicon substrate forms a gate dielectric. Typical processes for growth of dielectric films include oxidation, chemical vapor deposition and atomic layer deposition processes. As integrated circuit devices shrink, the thickness of the gate dielectric needs to shrink proportionally. However, semiconductor manufacturers have reached the limit to which the thickness of conventional gate dielectric materials can be decreased without compromising the electrical characteristics. Rather than degrading the dielectric properties by using a silicon dioxide dielectric that is only a few atomic layers thick, equivalent dielectric performance can be achieved by substituting the silicon dioxide for a thicker layer of a new material exhibiting a higher dielectric constant. Therefore, new compositions or methods to produce a dielectric film with a higher dielectric constant than silicon dioxide (referred to as “high-k dielectrics”) are required. These “high-k dielectrics” must have a low leakage current through the gate dielectric. Thus, it is desirable to develop new compositions and methods of depositing dielectric films with the required higher dielectric properties so that films with more than one or two layers of atoms can be deposited. Due to the requirements for thin dielectric films, having uniform coverage of material that is very high quality is critical to the performance of the gate dielectric.

Of particular interest is the formation of silicon oxynitride (“SiON”) films. Forming a SiON dielectric film typically involves feeding a silicon source, an oxygen source and a nitrogen source (collectively referred to herein as the “dielectric precursors”) in the proper relative amounts to a deposition device wherein a silicon substrate is held at an elevated temperature. The dielectric precursors are fed to a deposition chamber through a “delivery system.” A “delivery system” is the system of measuring and controlling the amounts of the various dielectric precursors being fed to the deposition chamber. Various delivery systems are known to one skilled in the art. Once in the deposition chamber, the dielectric precursors are deposited on the silicon substrate to form a dielectric film in a “forming” step. A “forming” step or steps, as used in this application, is the step or steps wherein materials are deposited on the silicon substrate or wherein the molecular composition or structure of the film on the silicon substrate is modified. The “desired final composition” of the dielectric film is the precise chemical composition and atomic structure of the dielectric gate after the last forming step is complete. The silicon sources available in the art prior to the current invention typically use a liquid precursor containing the desired silicon compound in a solvent.

U.S. Patent Publication No. U.S. 2003/0207549, PAJ Patent Application No. 2000272283, U.S. Pat. No. 0,639,9208, and U.S. Patent Publication No. 2003/0207549 disclose information relevant to forming dielectric films. However, these references suffer from one or more of the disadvantages discussed below.

Some gate dielectric-forming processes require multiple forming steps. For instance, a dielectric film may be formed by depositing silicon on a substrate in a first step followed by a second “post deposition step” wherein the composition or structure of the deposited silicon film is modified to achieve the desired final composition of a SiON gate dielectric film. An example of a post deposition step is rapid thermal annealing in an environment that is filled of nitrogen or ammonia. Because control of the film composition is important in dielectric film deposition processes, the fewer the steps, the better the control of the process, and the higher the quality (reflected by dielectric constant, density, contamination, composition and other quality control properties) and conformality (the ability of the film to evenly deposit on all surfaces and shapes of substrate) of the dielectric film.

It is known in the art that any silicon sources that contain carbon in the ligands can lead to carbon in the film and result in degraded electrical properties. Furthermore, any chlorine incorporated in dielectric films is undesirable due to its harmful effect on the electrical properties of the film and the stability of the chlorine in the film (the stability makes it hard to remove chlorine from the dielectric film). Also, the presence of chlorine in the silicon source results in the generation of chloride based particulates in the reaction chamber and deposits in the exhaust system. Thus, to achieve ideal electrical properties and to minimize particulate generation and tool downtime due to exhaust system cleaning, it is desirable to deposit dielectric films from precursors free of carbon or chlorine in the atomic structure.

Vaporizing silicon precursor streams can also lead to problems with film composition control. When the silicon source is supplied in liquid form, it must be vaporized before being introduced into the deposition chamber. Some processes known in the art use a vaporizer to vaporize the liquid silicon source. Vaporizing streams can lead to variable feed concentrations and formation of silicon residues in the vaporizer that can flake off and enter the chamber. The vaporization also requires additional equipment that introduces further complications in processing as well as additional maintenance requirements compared to an all gas phase delivery system.

Bubbling a carrier gas through a liquid precursor can also cause quality problems. In some processes, a silicon source is fed by bubbling a carrier gas through a liquid silicon source. In these processes, the composition of the stream transporting the silicon source to the deposition chamber can vary with temperature and pressure in the bubbling system. This variability in stream composition leads to variability in the composition of the dielectric film or changes in the deposition rate of the film, which are significant quality control issues.

For the foregoing reasons, it is desirable to form a dielectric film of the final desired composition in a single forming step. Furthermore, the film should be free of any chlorine or carbon in the molecular structure. Finally, it is desirable to have a silicon source that is in the vapor phase at process feed conditions to avoid the need to vaporize a liquid silicon source or bubble a carrier gas through a liquid source.

### SUMMARY

The current invention is directed to methods and compositions that satisfy the need to form a thin SiON dielectric film with high electrical qualities, and high conformality. The current invention avoids using multiple forming steps to assure uniform coverage and high conformality. Furthermore, the current invention provides a film that is free of carbon and chlorine and uses precursors that are free of carbon and chlorine, both of which can degrade the electrical properties of the film. Finally, the current invention avoids the quality and conformality issues that can occur when vaporizing a liquid silicon precursor solution or bubbling a carrier gas through a liquid silicon source.

The SiON dielectric film of the current invention is formed by feeding a plurality of dielectric precursors (“dielectric precursors” being a silicon source, an oxygen source, and a nitrogen source) to a deposition device, and forming a dielectric film with the desired final composition in a single forming step. In other words, there is no need for a post deposition step to achieve the desired final composition the dielectric film. Feeding of a plurality of dielectric precursors to the deposition device is effectively concurrent. The dielectric film forms on a silicon substrate in a single forming step without using a post deposition step to adjust the composition of the dielectric precursors in the dielectric film. The resulting dielectric film has the desired SiON composition and is absent carbon and chlorine to provide the highest quality dielectric properties.

The current invention uses a vapor phase silicon precursor for the deposition of SiON films of desired stochiometry. The vapor phase silicon precursor is sufficiently volatile at temperatures above 15° C. to supply the process as a vapor without bubbling a carrier gas through a liquid or heating in a vaporizer. This eliminates the control and quality problems associated with having to vaporize precursors or bubble a carrier gas through a liquid to feed the silicon source. Furthermore, the vapor phase silicon precursor is carbon and chlorine free, eliminating the undesirable effects of carbon and chlorine in the dielectric film. Finally, the current inventive method produces a dielectric film of the desired final composition is a single step.

The silicon source of a SiON film of the current invention is injected into the deposition chamber effectively concurrent with the oxygen source and nitrogen source. The silicon source is in the vapor phase at process feed conditions. That is, the silicon source flows from the source container through the feed measurement and control system as a vapor without the need to be vaporized or without using a carrier gas. However, a gas phase inert may be used to dilute the silicon mixture if needed to obtain accurate flow measurements. Furthermore, the silicon source does not have any atoms of carbon, or chlorine in the molecular structure of the compound. Preferred silicon sources that are carbon and chlorine free are, but are not limited to, the following compounds or mixtures of the following compounds:
1) Trisilylamine; 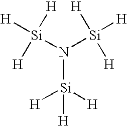
2) Disilylamine; 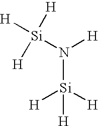
3) Silylamine; 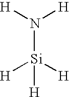
4) Tridisilylamine; 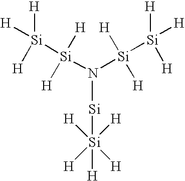
5) Aminodisilylamine; 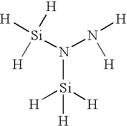
6) Tetrasilyldiamine; and 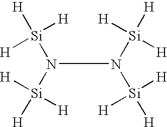
7) Disilane derivatives, wherein any H may be replaced with a NH₂.

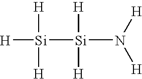

The oxygen and nitrogen sources are injected into the deposition chamber concurrently with the silicon source. Preferred oxygen and nitrogen sources are free of carbon and/or chlorine in their molecular structures.

The reaction of the dielectric precursors in the deposition chamber leads to the formation of a SiON film on the silicon substrate. The composition of the dielectric film can be precisely controlled by precisely controlling the flow rates of each of the dielectric precursors independently.

The reaction of the dielectric precursors in the deposition chamber forms a dielectric film of the desired final composition in a single reaction step. There is no requirement for a post deposition step wherein the composition of the dielectric film is modified by a step after the dielectric precursors are deposited on the substrate.

Because the silicon, oxygen and nitrogen sources in this invention are all carbon and chlorine free, the resulting dielectric film has excellent properties, including a high dielectric constant.

### DESCRIPTION OF THE DRAWINGS

FIG. 1 is a flow chart of the steps of forming a SiON dielectric film.

FIG. 2 is a flow chart of Prior Art steps of forming a SiON dielectric film.

### DESCRIPTION

The present invention is directed to a method of forming SiON dielectric films on semiconductor pieces and the product formed by that process. The present invention is applicable to chemical vapor deposition, plasma enhanced chemical vapor deposition, and atomic layer deposition processes as well as others known to one skilled in the art.

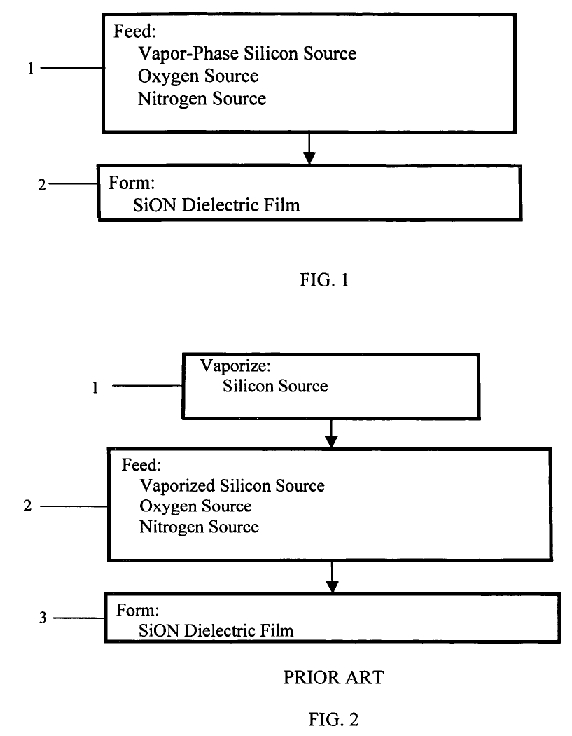

Referring to FIG. 1, during the feed step 1, a silicon source, an oxygen source, and a nitrogen source (collectively referred to as the dielectric precursors) are fed to a deposition chamber where a silicon substrate (on which deposition is needed) is placed at an elevated temperature. The deposition chamber is typically maintained between about 300 to about 900° C. Preferably the surface of the work piece in the deposition chamber will be between about 450 to about 600° C. The feeding of the dielectric precursors is effectively concurrent (atomic layer deposition involves high-speed sequential pulses of feed materials, which for the purposes of this invention is effectively concurrent).

Referring to FIG. 1, during the feed step 1, the silicon source is controllably injected into the deposition chamber effectively concurrent with the other dielectric precursors or silicon film components. In one preferred embodiment, a silicon source is in the vapor phase at process feed conditions. That is, the silicon source of one preferred embodiment has a vapor pressure of greater than about 50 torr at 20° C., sufficient to exist in the vapor phase in the feed control system without the need for vaporization or bubbler equipment in the delivery system. Trisilylamine, one preferred silicon source, may be stored as a liquid, but has sufficient vapor pressure (greater than about 350 torr vapor pressure at 20° C.) to be in the vapor phase in the delivery system without the need to use a vaporizer or bubbler system. Because the silicon source is in the vapor phase, it can be accurately measured and controlled with conventional devices know in the art, and is not affected by deposits in a vaporizer or swings in feed conditions during vaporization of the silicon source.

Still referring to FIG. 1, preferred embodiments of the feed step 1 include, but are not limited to, the use a silicon source absent carbon or chlorine in the molecular structure. Thus, the dielectric film is free of carbon and chlorine, resulting in the optimum electrical properties.

Still referring FIG. 1, preferred embodiments of the feed step 1 include, but are not limited to, feeding the oxygen and nitrogen sources into the deposition chamber concurrently with the silicon source. Various preferred embodiments use nitrogen sources are free of carbon and/or chlorine in their molecular structures. It is not required that nitrogen be fed as a separate stream. The nitrogen source can be the same as the silicon source, or the oxygen source. Preferred oxygen sources of the current invention are also free of carbon and/or chlorine in their molecular structures. Preferred embodiments include, but are not limited to oxygen, nitrous oxide, or ozone as the oxygen source. The nitrogen source of one preferred embodiment is ammonia. The oxygen and nitrogen sources are fed and controlled with devices known to one skilled in the art.

Referring again to FIG. 1, the deposition and reaction of dielectric precursors in the deposition chamber leads to the formation of a SiON film on the heated silicon substrate during the forming step 2. The forming step 2 forms a dielectric film of the final desired composition. One preferred SiON film would be formed by feeding trisilylamine, ammonia and nitrous oxide.

Referring again to FIG. 1, the composition of the SiON dielectric film can be controlled by varying the flow of each of the dielectric precursors independently during the feeding step 1. Because the feed rate of the dielectric precursors are independently controllable, the composition of the resulting dielectric film is controllable over a wide range without changing the composition of the silicon source.

Referring to FIG. 1, the feeding of the dielectric precursors to the deposition chamber results in the formation of a dielectric film of the desired final composition in a single forming step 2. There is no requirement for a post deposition step wherein the composition or structure of the dielectric film is modified after some or all of the dielectric precursors are deposited on the substrate to achieve the desired final composition.

Although the present invention has been described in considerable detail with reference to certain preferred versions thereof, other versions are possible. For example, the composition and method may be practiced in a process other then chemical vapor deposition or atomic layer deposition. In addition, the deposition of dielectric films can be accomplished at a variety of temperature and conditions. Furthermore, the invention may include a variety of silicon, oxygen and nitrogen sources known in the art. Therefore, the spirit and scope of the appended claims should not be limited to the description of one of the preferred versions contained herein. The intention of the applicants is to cover all modifications, equivalents, and alternatives falling within the spirit and scope of the invention as defined by the appended claims.

1. A method for forming a SiON dielectric film comprising the steps of:
feeding a plurality of dielectric precursors to a deposition device, wherein said dielectric precursors comprise a silicon source, an oxygen source, and a nitrogen source; and
forming a dielectric film, wherein said dielectric film is formed with the desired final composition absent a post deposition step.

2. The method of claim 1, wherein said silicon source comprises a molecular structure absent carbon.

3. The method of claim 1, wherein said silicon source comprises a molecular structure absent chlorine.

4. The method of claim 1, wherein said silicon source in the vapor phase in the delivery system.

5. The method of claim 1, absent a step wherein said silicon source is vaporized.

6. The method of claim 1, absent a step wherein said silicon source is delivered by bubbling a gas through a liquid silicon source.

7. The method of claim 1, wherein said silicon source has a vapor pressure great than about 50 torr at about 20° C.

8. The method of claim 1, wherein said silicon source is selected from the group consisting of trisilylamine, disilylamine, silylamine, tridisilylamine, aminodisilylamine, tetrasilyldiamine, disilane, derivatives of disilane, and mixtures thereof.

9. The method of claim 1, wherein said silicon source is trisilylamine.

10. The method of claim 1, wherein said oxygen source comprises a molecular structure absent carbon.

11. The method of claim 1, wherein said oxygen source comprises a molecular structure absent chlorine.

12. The method of claim 1, wherein said oxygen source is selected from the group consisting of oxygen, nitrous oxide, ozone, and mixtures thereof.

13. The method of claim 1, wherein said nitrogen source comprises a molecular structure absent carbon.

14. The method of claim 1, wherein said nitrogen source comprises a molecular structure absent chlorine.

15. The method of claim 1, wherein said nitrogen source is the same as said silicon source, or said oxygen source.

16. The method of claim 1, wherein said nitrogen source is ammonia.

17. The method of claim 1, wherein said forming a dielectric film step is completed using a chemical vapor deposition process.

18. The method of claim 1, wherein said forming a dielectric film step is completed using an atomic layer deposition process.

19. A SiON dielectric film prepared by a process comprising the steps of:
feeding a plurality of dielectric precursors to a deposition device, wherein said dielectric precursors comprise a silicon source, an oxygen source, and a nitrogen source; and
forming a dielectric film, wherein said dielectric film is formed with the desired final composition absent a post deposition step.

20. The dielectric film of claim 19, wherein said silicon source comprises a molecular structure absent carbon.

21. The dielectric film of claim 19, wherein said silicon source comprises a molecular structure absent chlorine.

22. The dielectric film of claim 19, wherein said silicon source is in the vapor phase in the delivery system.

23. The dielectric film of claim 19, absent a step wherein said silicon source is vaporized.

24. The dielectric film of claim 19, absent a step wherein said silicon source is delivered by bubbling a gas through a liquid silicon source.

25. The dielectric film of claim 19, wherein said silicon source has a vapor pressure great than about 50 torr at about 20° C.

26. The dielectric film of claim 19, wherein said silicon source is selected from the group consisting of trisilylamine, disilylamine, silylamine, tridisilylamine, aminodisilylamine, tetrasilyldiamine, disilane, derivatives of disilane, and mixtures thereof.

27. The dielectric film of claim 19, wherein said silicon source is trisilylamine.

28. The dielectric film of claim 27, wherein the source of said oxygen is nitrous oxide.

29. The dielectric film of claim 28, wherein the source of said nitrogen is ammonia.

30. The dielectric film of claim 19, wherein the source of said oxygen comprises a molecular structure absent carbon.

31. The dielectric film of claim 19, wherein the source of said oxygen comprises a molecular structure absent chlorine.

32. The dielectric film of claim 19, wherein said oxygen source is selected from the group consisting of oxygen, nitrous oxide, ozone, and mixtures thereof.

33. The dielectric film of claim 19, wherein the source of said nitrogen comprises a molecular structure absent carbon.

34. The dielectric film of claim 19, wherein the source of said nitrogen comprises a molecular structure absent chlorine.

35. The dielectric film of claim 19, wherein said nitrogen source is the same as said silicon source, or said oxygen source.

36. The dielectric film of claim 19, wherein said nitrogen source is ammonia.
